(19) United States
(12) Patent Application Publication
(10) Pub. No.: US 2025/0096033 A1
(43) Pub. Date: Mar. 20, 2025

(54) METHOD OF MANUFACTURING SEMICONDUCTOR DEVICE

(71) Applicant: NANYA TECHNOLOGY CORPORATION, New Taipei City (TW)

(72) Inventor: Ying-Cheng CHUANG, Taoyuan City (TW)

(21) Appl. No.: 18/369,148

(22) Filed: Sep. 16, 2023

(51) Int. Cl. H01L 21/762; H01L 21/033; H01L 21/3105

(52) U.S. Cl. CPC H01L 21/76229; H01L 21/0332; H01L 21/0334; H01L 21/31053

(57) ABSTRACT

The present disclosure provides a method of manufacturing a semiconductor device. The method includes: providing a substrate having an array area and a periphery area; forming an etch stop layer on a top surface of the substrate in the array area and the periphery area; forming a patterned mask layer on a top surface of the etch stop layer in the array area and the periphery area, in which the patterned mask layer has a plurality of hollowed portions; forming a plurality of trenches on the top surface of the etch stop layer in the array area and the periphery area through the hollowed portions of the patterned mask layer, in which the trenches run through the etch stop layer and are recessed from the top surface of the substrate; removing the patterned mask layer; and depositing an oxide layer to fill the trenches.

### BACKGROUND

### Field of Invention

The present invention relates to a method of manufacturing a semiconductor device.

### Description of Related Art

With the evolution of generations of semiconductor processes, there will be challenges of trench filling process. For example, one of the related challenges brought by the semiconductor device is that “tip problem” may occur during the process of forming and filling the trench if the trench is not formed and filled in a proper manner (for example, utilizing an approach that is prone to generating polymers affecting the profile of the trenches). More specifically, the tip problem may occur in the bottom of the trenches (for example, the bottom of shallow trench isolation (STI)). The tip problem is likely to cause electrical field variation and short problem (for example, the leakage current) in subsequent related processes, thereby reducing the electrical performance of the entire semiconductor device.

### SUMMARY

In view of this, one purpose of the present disclosure is to provide a method of manufacturing a semiconductor device that can solve the aforementioned problems.

In order to achieve the above objective, according to an embodiment of the present disclosure, a method of manufacturing a semiconductor device includes: providing a substrate having an array area and a periphery area; forming an etch stop layer on a top surface of the substrate in the array area and the periphery area; forming a patterned mask layer on a top surface of the etch stop layer in the array area and the periphery area, in which the patterned mask layer has a plurality of hollowed portions, and in which the patterned mask layer includes oxide; forming a plurality of trenches on the top surface of the etch stop layer in the array area and the periphery area through the hollowed portions of the patterned mask layer, in which the trenches run through the etch stop layer and are recessed from the top surface of the substrate; removing the patterned mask layer; and depositing an oxide layer to fill the trenches by a deposition process.

In one or more embodiments of the present disclosure, depositing the oxide layer is performed such that the oxide layer fully fills the trenches.

In one or more embodiments of the present disclosure, removing the patterned mask layer is performed before depositing the oxide layer.

In one or more embodiments of the present disclosure, the patterned mask layer has a thickness in a range between 30 nm and 150 nm.

In one or more embodiments of the present disclosure, forming the patterned mask layer is performed before depositing the oxide layer.

In one or more embodiments of the present disclosure, depositing the oxide layer is performed such that a top surface of the oxide layer and the top surface of the etch stop layer are coplanar.

In one or more embodiments of the present disclosure, the method further includes removing a portion of the oxide layer by a planarization process.

In one or more embodiments of the present disclosure, removing the portion of the oxide layer is performed such that a top surface of the oxide layer and the top surface of the etch stop layer are coplanar.

In one or more embodiments of the present disclosure, forming the trenches on the top surface of the etch stop layer in the array area and the periphery area through the hollowed portions of the patterned mask layer is performed such that an aspect ratio of the trenches in the array area and an aspect ratio of the trenches in the periphery area are different.

In one or more embodiments of the present disclosure, forming the trenches on the top surface of the etch stop layer in the array area and the periphery area through the hollowed portions of the patterned mask layer is performed such that an aspect ratio of a depth to a width of the trenches in the array area is greater than an aspect ratio of a depth to a width of the trenches in the periphery area.

In one or more embodiments of the present disclosure, the etch stop layer has a thickness in a range between 15 nm and 50 nm.

In one or more embodiments of the present disclosure, the etch stop layer comprises nitride.

In order to achieve the above objective, according to an embodiment of the present disclosure, a method of manufacturing a semiconductor device includes: providing a substrate having an array area and a periphery area; forming an etch stop layer on a top surface of the substrate in the array area and the periphery area; forming a patterned mask layer on a top surface of the etch stop layer in the array area and the periphery area, in which the patterned mask layer has a plurality of hollowed portions, and in which the patterned mask layer includes oxide; forming a plurality of trenches on the top surface of the etch stop layer in the array area and the periphery area through the hollowed portions of the patterned mask layer, in which the trenches run through the etch stop layer and are recessed from the top surface of the substrate; removing the patterned mask layer; overfilling the trenches by depositing an oxide layer; and removing a portion of the oxide layer by a planarization process, such that a top surface of the oxide layer and the top surface of the etch stop layer are coplanar.

In one or more embodiments of the present disclosure, removing the patterned mask layer is performed before depositing the oxide layer.

In one or more embodiments of the present disclosure, the patterned mask layer has a thickness in a range between 30 nm and 150 nm.

In one or more embodiments of the present disclosure, forming the patterned mask layer is performed before depositing the oxide layer.

In one or more embodiments of the present disclosure, forming the trenches on the top surface of the etch stop layer in the array area and the periphery area through the hollowed portions of the patterned mask layer is performed such that an aspect ratio of the trenches in the array area and an aspect ratio of the trenches in the periphery area are different.

In one or more embodiments of the present disclosure, forming the trenches on the top surface of the etch stop layer in the array area and the periphery area through the hollowed portions of the patterned mask layer is performed such that an aspect ratio of a depth to a width of the trenches in the array area is greater than an aspect ratio of a depth to a width of the trenches in the periphery area.

In one or more embodiments of the present disclosure, the etch stop layer has a thickness in a range between 15 nm and 50 nm.

In one or more embodiments of the present disclosure, forming the trenches on the top surface of the etch stop layer in the array area and the periphery area through the hollowed portions of the patterned mask layer is performed such that the pattern mask layer is removed simultaneously.

In summary, in the method of manufacturing the semiconductor device of the present disclosure, since the patterned mask layer includes oxide, there are no polymers generated during the step of forming the trenches, thereby preventing the tip problem due to etch selectivity occurring on the bottom of the trenches. In the method of manufacturing the semiconductor device of the present disclosure, since forming the etch stop layer is performed before removing the portion of the oxide layer, the etch stop layer can prevent the oxide layer being over-etched, such that the top surface of the oxide layer is leveled with the top surface of the etch stop layer. In the method of manufacturing the semiconductor device of the present disclosure, since the patterned mask layer is configured as sacrificial patterned mask, the manufacturing parameters in subsequent related process are no longer needed to be modified, thereby reducing the time and cost of the whole manufacturing process. Overall, the method of manufacturing the semiconductor device of the present disclosure improves the electrical performance of the entire semiconductor device.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a flow chart of a method of manufacturing a semiconductor device in accordance with an embodiment of the present disclosure;

FIG. 2 is a cross-sectional view of an intermediate stage of manufacturing a semiconductor device in accordance with an embodiment of the present disclosure;

FIG. 3 is a cross-sectional view of an intermediate stage of manufacturing the semiconductor device in accordance with an embodiment of the present disclosure;

FIG. 4 is a cross-sectional view of an intermediate stage of manufacturing the semiconductor device in accordance with an embodiment of the present disclosure;

FIG. 5 is a cross-sectional view of an intermediate stage of manufacturing the semiconductor device in accordance with an embodiment of the present disclosure;

FIG. 6 is a cross-sectional view of an intermediate stage of manufacturing the semiconductor device in accordance with an embodiment of the present disclosure;

FIG. 7 is a cross-sectional view of an intermediate stage of manufacturing the semiconductor device in accordance with another embodiment of the present disclosure; and

FIG. 8 is a cross-sectional view of an intermediate stage of manufacturing the semiconductor device in accordance with another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

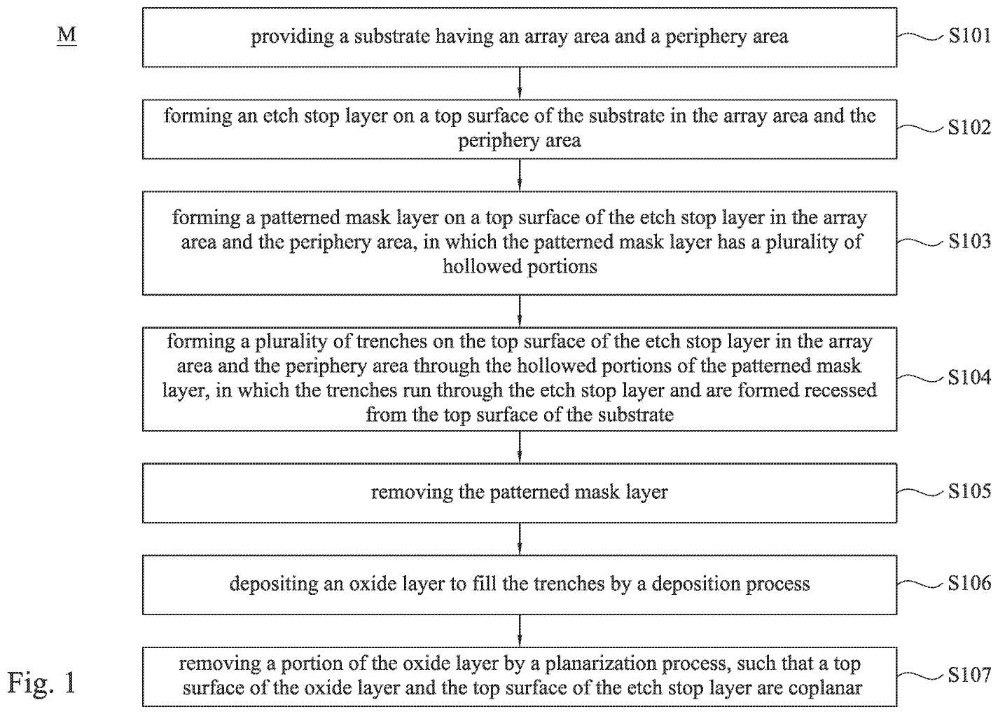

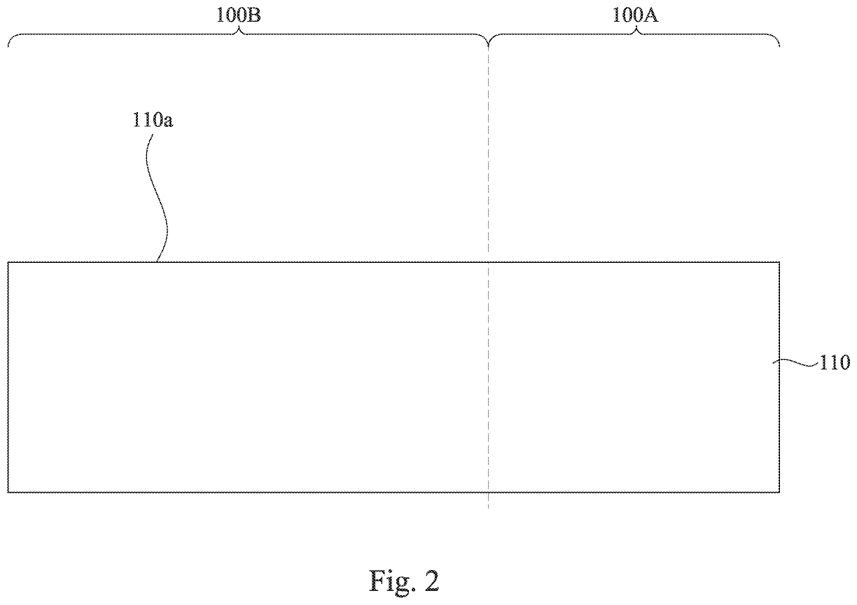

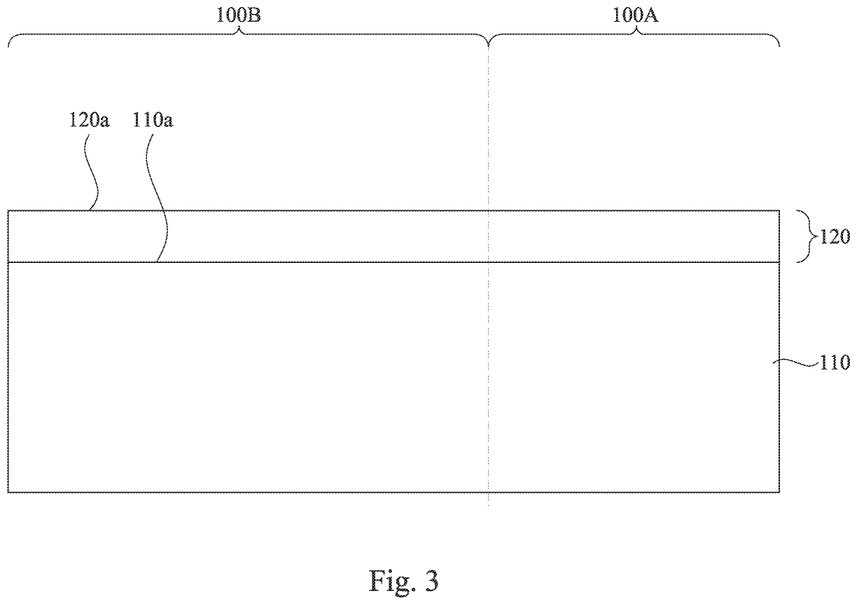

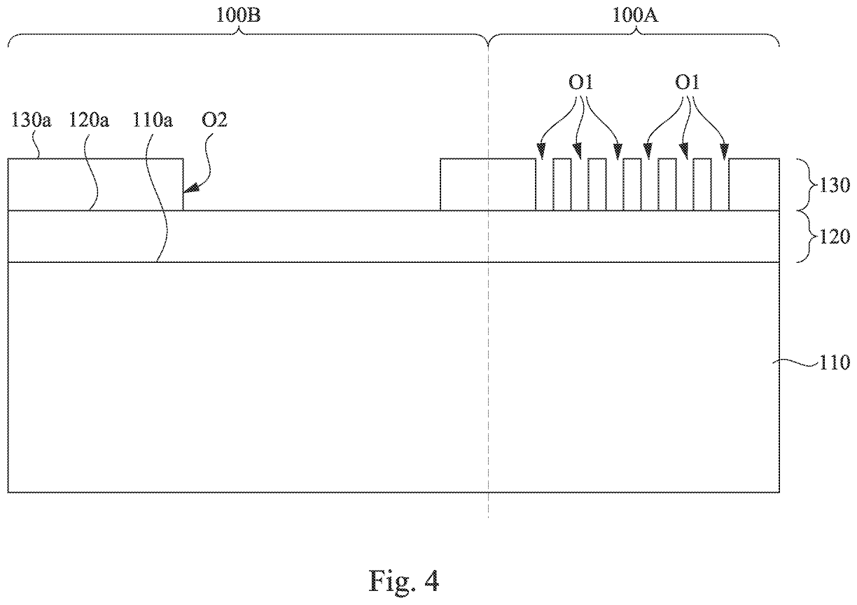

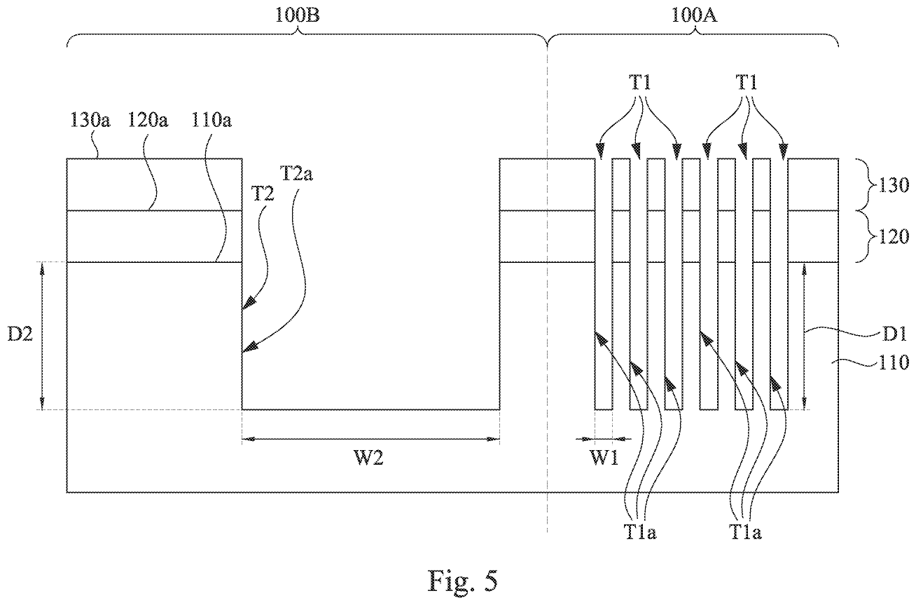

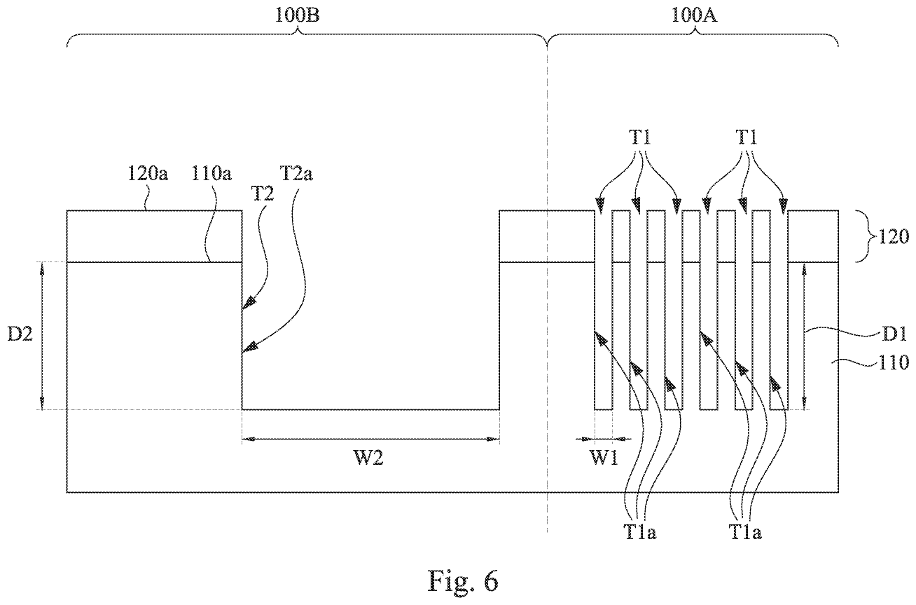

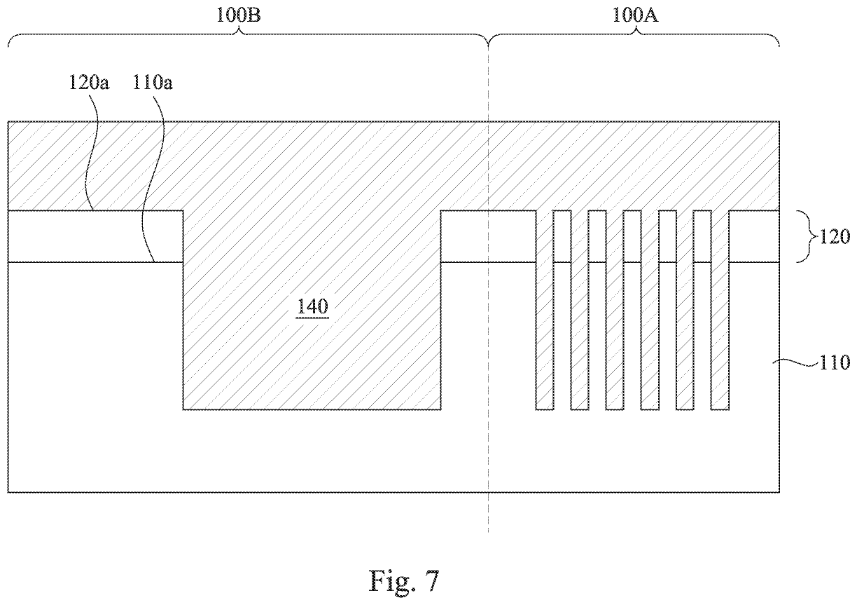

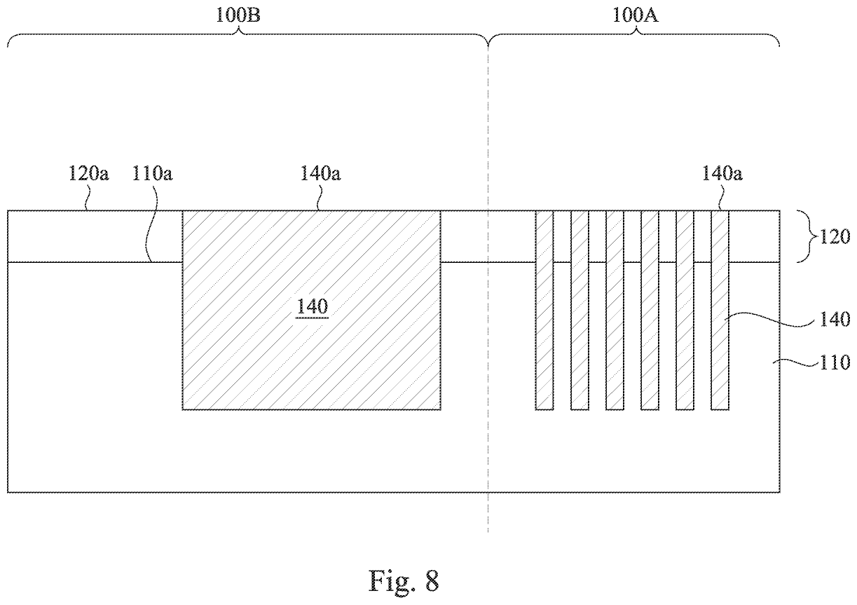

Reference is made to FIG. 1. FIG. 1 is a flow chart of a method M of manufacturing a semiconductor device 100 as shown in FIG. 8 in accordance with an embodiment of the present disclosure. The method M shown in FIG. 1 includes a step S101, a step S102, a step S103, a step S104, a step S105, a step S106, and a step S107. Please refer to FIG. 1 and FIG. 2 for better understanding the step S101, refer to FIG. 1 and FIG. 3 for better understanding the step S102, refer to FIG. 1 and FIG. 4 for better understanding the step S103, refer to FIG. 1 and FIG. 5 for better understanding the step S104, refer to FIG. 1 and FIG. 6 for better understanding the step S105, refer to FIG. 1 and FIG. 7 for better understanding the step S106, and refer to FIG. 1 and FIG. 8 for better understanding the step S107.

Step S101, step S102, step S103, step S104, step S105, step S106, and step S107 are described in detail below.

In step S101, a substrate 110 is provided.

Reference is made to FIG. 1 and FIG. 2. FIG. 2 is a cross-sectional view of an intermediate stage of manufacturing a semiconductor device 100 in accordance with an embodiment of the present disclosure. In this embodiment, the substrate 110 is formed. As shown in FIG. 2, the substrate 110 has an array area 100A and a periphery area 100B. As shown in FIG. 2, the substrate 110 has a top surface 110a, and the top surface 110a is exposed.

In some embodiments, the substrate 110 may be silicon-based substrate. In some embodiments, the substrate 110 may include a material, such as monocrystalline silicon, polysilicon, amorphous silicon, or the like. However, any suitable material may be utilized.

In some embodiments, the substrate 110 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electro-chemical plating), electroless plating, or the like. The present disclosure is not intended to limit the methods of forming the substrate 110.

In step S102, an etch stop layer 120 is formed.

Reference is made to FIG. 1 and FIG. 3. FIG. 3 is a cross-sectional view of an intermediate stage of manufacturing a semiconductor device 100 in accordance with an embodiment of the present disclosure. In this embodiment, an etch stop layer 120 is formed on the top surface 110a of the substrate 110 in the array area 100A and the periphery area 100B of the substrate 110. As shown in FIG. 3, the etch stop layer 120 has a top surface 120a, and the top surface 120a is exposed. In some embodiments, the etch stop layer 120 is configured as a stop layer in subsequent steps.

In some embodiments, the etch stop layer 120 may include a material, such as silicon nitride (SiₓN_{y}), titanium nitride (TiₓN_{y}), or the like. However, any suitable material may be utilized.

In some embodiments, the etch stop layer 120 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electro-chemical plating), electroless plating, or the like. The present disclosure is not intended to limit the methods of forming the etch stop layer 120.

In step S103, a patterned mask layer 130 is formed.

Reference is made to FIG. 1 and FIG. 4. FIG. 4 is a cross-sectional view of an intermediate stage of manufacturing the semiconductor device 100 in accordance with an embodiment of the present disclosure. In this embodiment, the patterned mask layer 130 is disposed over the substrate 110. In some embodiments, the patterned mask layer 130 is disposed on the etch stop layer 120. As shown in FIG. 4, the patterned mask layer 130 has a plurality of hollowed portions O1 and hollowed portions O2. The hollowed portions O1 are located in the array area 100A, whereas the hollowed portions O2 are located in the periphery area 100B. To simplify the description, the hollowed portions O2 are depicted as a singular hollowed portion in FIG. 4. As shown in FIG. 4, the patterned mask layer 130 has a top surface 130a, and the top surface 130a is exposed.

In some embodiments, the hollowed portions O1 and the hollowed portions O2 may be formed by any suitable method, for example, wet etching, dry etching, or the like. The present disclosure is not intended to limit the methods of forming the hollowed portions O1 and the hollowed portions O2.

In some embodiments, a width of each of the hollowed portions O2 is greater than a width of each of the hollowed portions O1.

In some embodiments, the patterned mask layer 130 includes oxide. In some embodiments, the patterned mask layer 130 may include a material, such as silicon oxide (SiO₂), or the like. However, any suitable material may be utilized.

In some embodiments, the patterned mask layer 130 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electro-chemical plating), electroless plating, or the like. The present disclosure is not intended to limit the methods of forming the patterned mask layer 130.

In step S104, a plurality of trenches T1 and a plurality of trenches T2 are formed.

Reference is made to FIG. 1 and FIG. 5. FIG. 5 is a cross-sectional view of an intermediate stage of manufacturing the semiconductor device 100 in accordance with an embodiment of the present disclosure. In step S102, a plurality of trenches T1 and trenches T2 are formed on the top surface 110a of the substrate 110 the array area 100A and in the periphery area 100B through the hollowed portions O1 and the hollowed portions O2 of the patterned mask layer 130. As shown in FIG. 5, the trenches T1 and the trenches T2 are respectively formed through the hollowed portions O1 and the hollowed portions O2 of the patterned mask layer 130. In some embodiments, the trenches T1 and the trenches T2 pass through the etch stop layer 120. In some embodiments, the trenches T1 and the trenches T2 run through the etch stop layer 120 and are recessed from the top surface 110a of the substrate 110. In some embodiments, each of the trenches T1 has an inner surface Tla and each of the trenches T2 has an inner surface T2a.

As shown in FIG. 5, each of the trenches T1 includes a depth D1 and a width W1. In some embodiments, the depth D1 is defined as a distance from the top surface 110a of the substrate 110 to the bottom of each of the trenches T1. In some embodiments, the depth D1 may be larger than the width W1, but the present disclosure is not limited thereto. In some embodiments, the depth D1 is about 300 nm. In some embodiments, the width W1 is in a range between about 8 nm and about 20 nm. In some embodiments, an aspect ratio of the depth D1 to the width W1 of the trench T1 is in a range from about 15 to about 37.5, but the present disclosure is not limited thereto.

As shown in FIG. 5, each of the trenches T2 includes a depth D2 and a width W2. In some embodiments, the depth D2 is defined as a distance from the top surface 110a of the substrate 110 to the bottom of each of the trenches T2. In some embodiments, the width W2 may be greater than the width W1. In some embodiments, the depth D2 may be less or greater than the width W2, but the present disclosure is not limited thereto.

In some embodiments, the depth D1 may be equal to the depth D2, but the present disclosure is not limited thereto.

In some embodiments, the aspect ratio of the depth D1 to the width W1 of each of the trenches T1 in the array area 100A is different from an aspect ratio of the depth D2 to the width W2 of each of the trenches T2 in the periphery area 100B. In some embodiments, the aspect ratio of the depth D1 to the width W1 of each of the trenches T1 in the array area 100A is less than the aspect ratio of the depth D2 to the width W2 of each of the trenches T2 in the periphery area 100B.

In some embodiments, the trenches T1 and the trenches T2 may be formed by any suitable method, for example, wet etching, dry etching, or the like. The present disclosure is not intended to limit the methods of forming the trenches T1 and the trenches T2.

In step S105, the patterned mask layer 130 is removed.

Reference is made to FIG. 1 and FIG. 6. FIG. 6 is a cross-sectional view of an intermediate stage of manufacturing a semiconductor device 100 in accordance with an embodiment of the present disclosure. In this embodiment, the patterned mask layer 130 is removed from the top surface 120a of the etch stop layer 120. As shown in FIG. 6, the patterned mask layer 130 is removed after step S104. In some embodiments, the patterned mask layer 130 is removed by a removing process.

In some embodiments, the patterned mask layer 130 may be removed by any suitable method, for example, wet etching, dry etching, or the like. The present disclosure is not intended to limit the methods of forming the patterned mask layer 130.

In some embodiments, the patterned mask layer 130 has a thickness in a range between about 30 nm and about 150 nm. In some embodiments in which the thickness of the patterned mask layer 130 is greater than 150 nm, the patterned mask layer 130 are not easily removed during step S105. In some embodiments in which the thickness of the patterned mask layer 130 is less than 30 nm, the patterned mask layer 130 may be overconsumed so that the trenches T1 and the trenches T2 are not easily pass through the etch stop layer 120 and recessed on the substrate 110 during step S104.

In some other embodiments, forming the trenches T1 and the trenches T2 on the top surface 120a of the etch stop layer 120 in the array area 100A and the periphery area 100B through the hollowed portions O1 and the hollowed portions O2 of the patterned mask layer 130 is performed such that the pattern mask layer 130 is removed simultaneously. In other words, step S104 and step S105 may be performed at the same time. More specifically, the pattern mask layer 130 is consumed as the trenches T1 and the trenches T2 are formed downward.

In step S106, an oxide layer 140 is deposited to fill the trenches T1 and the trenches T2.

Reference is made to FIG. 1 and FIG. 7. FIG. 7 is a cross-sectional view of an intermediate stage of manufacturing a semiconductor device 100 in accordance with an embodiment of the present disclosure. In step S106, an oxide layer 140 is deposited on the inner surface Tla of each of the trenches T1 and the inner surface T2a of each of the trenches T2 of the substrate 110. As shown in FIG. 7, the oxide layer 140 is formed on the top surface 120a of the etch stop layer 120 after step S105. More specifically, the oxide layer 140 is filled in the trenches T1 in the array area 100A and the trenches T2 in the periphery area 100B. In some embodiments, the trenches T1 and the trenches T2 are fully filled by the oxide layer 140. In some embodiments, the oxide layer 140 overfills the trenches T1 and the trenches T2.

In some embodiments, the oxide layer 140 may include a material, such as oxide. For example, the material may include silicon oxide (SiO₂) or the like. The present disclosure is not intended to limit the material of the oxide layer 140.

In some embodiments, the oxide layer 140 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electro-chemical plating), electroless plating, or the like. The present disclosure is not intended to limit the methods of forming the oxide layer 140.

In some embodiments, the oxide layer 140 may be deposited by a flowable chemical vapor deposition (FCVD) process, a spin-on dielectric coating deposition, or the like.

In step S107, a portion of the oxide layer 140 is removed.

Reference is made to FIG. 1 and FIG. 8. FIG. 8 is a cross-sectional view of an intermediate stage of manufacturing a semiconductor device 100 in accordance with an embodiment of the present disclosure. As shown in FIG. 8, a portion of the oxide layer 140 is removed and the semiconductor device 100 is formed. More specifically, the portion of the oxide layer 140 located on the top surface 120a of the etch stop layer 120 is removed during step S107. In some embodiments, removing the portion of the oxide layer 140 is performed by a planarization process. As shown in FIG. 8, removing the portion of the oxide layer is performed such that a top surface 140a of remaining portions of the oxide layer 140 and the top surface 120a of the etch stop layer 120 are coplanar. In other words, the top surface 140a of the oxide layer 140 is leveled to the top surface 120a of the etch stop layer 120.

In some embodiments, the planarization process may be performed by a chemical-mechanical planarization (CMP) process.

In some embodiments, the etch stop layer 120 has a thickness in a range between about 15 nm and about 50 nm. In some embodiments in which the thickness of the etch stop layer 120 is greater than 50 nm, the trenches T1 and the trenches T2 may not easily pass through the etch stop layer 120 and recessed on the substrate 110 during step S104. In some embodiments in which the thickness of the etch stop layer 120 is less than 15 nm, the etch stop layer 120 may be overconsumed during step S107.

By performing the method M shown in FIG. 1 of the present disclosure, the semiconductor device 100 with better electrical performance may be formed.

Based on the above discussions, it can be seen that in the method of manufacturing the semiconductor device of the present disclosure, since the patterned mask layer includes oxide, there are no polymers generated during the step of forming the trenches, thereby preventing the tip problem due to etch selectivity occurring on the bottom of the trenches. In the method of manufacturing the semiconductor device of the present disclosure, since forming the etch stop layer is performed before removing the portion of the oxide layer, the etch stop layer can prevent the oxide layer being over-etched, such that the top surface of the oxide layer is leveled with the top surface of the etch stop layer. In the method of manufacturing the semiconductor device of the present disclosure, since the patterned mask layer is configured as sacrificial patterned mask, the manufacturing parameters in subsequent related process are no longer needed to be modified, thereby reducing the time and cost of the whole manufacturing process. Overall, the method of manufacturing the semiconductor device of the present disclosure improves the electrical performance of the entire semiconductor device.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a semiconductor device, comprising:
providing a substrate having an array area and a periphery area;
forming an etch stop layer on a top surface of the substrate in the array area and the periphery area;
forming a patterned mask layer on a top surface of the etch stop layer in the array area and the periphery area, wherein the patterned mask layer has a plurality of hollowed portions, and wherein the patterned mask layer includes oxide;
forming a plurality of trenches on the top surface of the etch stop layer in the array area and the periphery area through the hollowed portions of the patterned mask layer, wherein the trenches run through the etch stop layer and are recessed from the top surface of the substrate;
removing the patterned mask layer; and
depositing an oxide layer to fill the trenches by a deposition process.

2. The method of claim 1, wherein depositing the oxide layer is performed such that the oxide layer fully fills the trenches.

3. The method of claim 1, wherein removing the patterned mask layer is performed before depositing the oxide layer.

4. The method of claim 1, wherein the patterned mask layer has a thickness in a range between 30 nm and 150 nm.

5. The method of claim 1, wherein forming the patterned mask layer is performed before depositing the oxide layer.

6. The method of claim 1, wherein depositing the oxide layer is performed such that a top surface of the oxide layer and the top surface of the etch stop layer are coplanar.

7. The method of claim 1, further comprising removing a portion of the oxide layer by a planarization process.

8. The method of claim 7, wherein removing the portion of the oxide layer is performed such that a top surface of the oxide layer and the top surface of the etch stop layer are coplanar.

9. The method of claim 1, wherein forming the trenches on the top surface of the etch stop layer in the array area and the periphery area through the hollowed portions of the patterned mask layer is performed such that an aspect ratio of the trenches in the array area and an aspect ratio of the trenches in the periphery area are different.

10. The method of claim 1, wherein forming the trenches on the top surface of the etch stop layer in the array area and the periphery area through the hollowed portions of the patterned mask layer is performed such that an aspect ratio of a depth to a width of the trenches in the array area is greater than an aspect ratio of a depth to a width of the trenches in the periphery area.

11. The method of claim 1, wherein the etch stop layer has a thickness in a range between 15 nm and 50 nm.

12. The method of claim 1, wherein the etch stop layer comprises nitride.

13. A method of manufacturing a semiconductor device, comprising:
providing a substrate having an array area and a periphery area;
forming an etch stop layer on a top surface of the substrate in the array area and the periphery area;
forming a patterned mask layer on a top surface of the etch stop layer in the array area and the periphery area, wherein the patterned mask layer has a plurality of hollowed portions, and wherein the patterned mask layer includes oxide;
forming a plurality of trenches on the top surface of the etch stop layer in the array area and the periphery area through the hollowed portions of the patterned mask layer, wherein the trenches run through the etch stop layer and are recessed from the top surface of the substrate;
removing the patterned mask layer;
overfilling the trenches by depositing an oxide layer; and
removing a portion of the oxide layer by a planarization process, such that a top surface of the oxide layer and the top surface of the etch stop layer are coplanar.

14. The method of claim 13, wherein removing the patterned mask layer is performed before depositing the oxide layer.

15. The method of claim 13, wherein the patterned mask layer has a thickness in a range between 30 nm and 150 nm.

16. The method of claim 13, wherein forming the patterned mask layer is performed before depositing the oxide layer.

17. The method of claim 13, wherein forming the trenches on the top surface of the etch stop layer in the array area and the periphery area through the hollowed portions of the patterned mask layer is performed such that an aspect ratio of the trenches in the array area and an aspect ratio of the trenches in the periphery area are different.

18. The method of claim 13, wherein forming the trenches on the top surface of the etch stop layer in the array area and the periphery area through the hollowed portions of the patterned mask layer is performed such that an aspect ratio of a depth to a width of the trenches in the array area is greater than an aspect ratio of a depth to a width of the trenches in the periphery area.

19. The method of claim 13, wherein the etch stop layer has a thickness in a range between 15 nm and 50 nm.

20. The method of claim 13, wherein forming the trenches on the top surface of the etch stop layer in the array area and the periphery area through the hollowed portions of the patterned mask layer is performed such that the pattern mask layer is removed simultaneously.
